(19) United States
(12) Patent Application Publication
(10) Pub. No.: US 2014/0283604 A1
(43) Pub. Date: Sep. 25, 2014

(54) THREE-DIMENSIONAL MICROELECTROMECHANICAL SYSTEMS STRUCTURE

(71) Applicant: The Regents of the University of Michigan, Ann Arbor, MI (US)

(72) Inventors: Khalil Najafi, Ann Arbor, MI (US); Mahdi Sadeghi, Ann Arbor, MI (US); Rebecca L. Peterson, Ann Arbor, MI (US); Yemin Tang, Ann Arbor, MI (US)

(73) Assignee: The Regents of the University of Michigan, Ann Arbor, MI (US)

(21) Appl. No.: 14/064,098

(22) Filed: Oct. 25, 2013

Related U.S. Application Data
(60) Provisional application No. 61/719,141, filed on Oct. 26, 2012.

(51) Int. Cl. B81B 7/00; H01L 41/08; G01P 15/125; H01L 37/00

(52) U.S. Cl. CPC B81B 7/0009; H01L 37/00; H01L 41/08; G01P 15/125
USPC 73/514.32; 310/306

(57) ABSTRACT

A three-dimensional microelectromechanical systems (MEMS) structure includes a substrate and having a height extending outwardly from the substrate and a largest lateral dimension orthogonal to the height. The largest lateral dimension is smaller than the height. A transducing element is operatively connected to the hair-like core and embedded within, formed on an outer surface of, or disposed at a root of the hair-like core. The transducing element is to receive an electrical core signal or a non-electrical core signal conveyed by the hair-like core. The transducing element is to convert the non-electrical core signal to an electrical output signal, convert the electrical core signal to an electrical output signal in a different format, convert the non-electrical core signal to a different non-electrical output signal, or convert the electrical core signal to a non-electrical output signal.

### CROSS-REFERENCE TO RELATED APPLICATION

This application claims the benefit of U.S. Provisional Application Ser. No. 61/719,141, filed Oct. 26, 2012, which is incorporated by reference herein.

### STATEMENT REGARDING FEDERALLY SPONSORED RESEARCH OR DEVELOPMENT

This invention was made with government support under W911NF-08-2-0004 awarded by the U.S. Army Research Office. The government has certain rights in the invention.

### BACKGROUND

Biomimetic sensing is using sensors created by human endeavor that mimic processes found in biological organisms. Biological structures include a myriad of structures, materials, and schemes to achieve superb sensing performance with extreme reliability and robustness. One structure commonly occurring in nature is the “hair.” In nature, hair-like structures such as cilia are involved in sensing acoustic phenomena, chemical composition and concentration, flow, pressure, and other properties of an environment around an organism. For example, there are hair-like structures involved in human hearing processes. Biological hair-like actuators and passive structures are also used for thermal management, filtering, fluid flow control, etc. For example, birds can cause their feathers to fluff to provide better insulation against cold weather.

### SUMMARY

A three-dimensional microelectromechanical systems (3-D MEMS) structure includes a substrate and a hair-like core having a height extending outwardly from the substrate and a largest lateral dimension orthogonal to the height. The largest lateral dimension is smaller than the height. A transducing element is operatively connected to the hair-like core and embedded within, formed on an outer surface of, or disposed at a root of the hair-like core. The transducing element is to receive an electrical core signal or a non-electrical core signal conveyed by the hair-like core. The transducing element is to convert the non-electrical core signal to an electrical output signal, convert the electrical core signal to an electrical output signal in a different format, convert the non-electrical core signal to a different non-electrical output signal, or convert the electrical core signal to a non-electrical output signal.

### BRIEF DESCRIPTION OF THE DRAWINGS

Features and advantages of examples of the present disclosure will become apparent by reference to the following detailed description and drawings, in which:

FIG. 1A is a schematic system block diagram of an example of a 3-D MEMS structure with a hair-like core in a biomimetic sensor system of the present disclosure;

FIG. 1B is a semi-schematic perspective view of an example of a 3-D MEMS structure with a plurality of hair-like cores in a biomimetic sensor system of the present disclosure;

FIG. 1C is a combined semi-schematic cross-section view and system block diagram of an example of a 3-D MEMS structure with a plurality of hair-like cores in a biomimetic sensor system of the present disclosure;

FIG. 2A is a semi schematic side view of a hot-wire hair airflow sensor according to the present disclosure;

FIG. 2B is a perspective view of a portion of the hair airflow sensor depicted in FIG. 2A showing detail of the substrate with a hair-like bond wire mounted on the substrate;

FIG. 2C is a perspective view of a portion of the hair airflow sensor depicted in FIG. 2A showing detail of the hair-like bond wire mounting arrangement;

FIG. 3 is a semi-schematic partial perspective view of a micro-hydraulic structure with hair-like cores attached on a bossed membrane according to the present disclosure with a cross-section through the micro-hydraulic structure;

FIG. 4 is a semi-schematic perspective view of an example of an array of hair-like cores attached on top of a 4-cell micro-hydraulic system according to the present disclosure, shown on a U.S. penny to convey relative size;

FIG. 5 is a semi-schematic, cross-sectional diagram showing an example of a three-dimensional MEMS structure integrated with electronics according to the present disclosure;

FIG. 6A is a semi-schematic perspective view of another example of an array of 3-D MEMS structures integrated with circuitry according to the present disclosure;

FIG. 6B shows a semi-schematic top view of the silicon side of a 5×5 array with a wire bond according to the present disclosure;

FIG. 6C shows an array of hair-like cores with metal connections running between the bonded interfaces according to the present disclosure;

FIG. 7A is a semi-schematic perspective view of an example of an array of hair sensors of the same dimension and type according to the present disclosure;

FIG. 7B is a semi-schematic perspective view of an example of an array of 3-D MEMS structures having different sizes and shapes, made of different materials, and all on the same substrate according to the present disclosure;

FIG. 7C is a semi-schematic perspective view showing a single hair sensor with post, mass and capacitive gaps to walls;

FIG. 8 is a semi-schematic view of still another example of an array of 3-D MEMS structures, showing various examples of 3-D structure cross-sections according to the present disclosure;

FIG. 9 is a top, perspective view of a 3-D pin (“hair”) integrated on top of a flexible Parylene membrane according to the present disclosure;

FIG. 10 is a semi-schematic perspective view of an array of 3-D MEMS structures on a flexible substrate according to the present disclosure;

FIG. 11 is a semi-schematic perspective view of a 3-D MEMS structure made using stereo-lithography with a cross-section through two hair-like cores according to the present disclosure;

FIG. 12 is a semi-schematic perspective view of a finalized hair-boss 3-D MEMS structure generated by stereo-lithography with adhesive and SLA tethers trimmed/cut to release the hairs;

FIG. 13A is a graph depicting a vibration table measurement result showing the mechanical-electrical response of a 5×5 acceleration sensor array when maximum acceleration level is swept from 1 g to 24 g at 40 Hz;

FIG. 13B is a graph depicting an analytical prediction of the result under the same conditions shown in FIG. 13A;

FIG. 14 is a semi-schematic perspective view depicting an array of hair-like cores with different heights, cross-sectional shapes, and made out of various material on the same substrate according to the present disclosure;

FIG. 15 is a semi-schematic perspective view of an example having hair-like cores in an array with some of the hair-like cores connected according to the present disclosure; and

FIG. 16 is a graph depicting test results from the structure depicted in FIG. 6B.

### DETAILED DESCRIPTION

The present disclosure relates generally to 3-dimensional (3-D) MEMS hair-like biomimetic structures. Examples of the 3-D MEMS structures of the present disclosure may include devices on hair-like structures to perform transduction functions. As such, the 3-D MEMS structures of the present disclosure may be sensors used to detect or measure a physical property and record, indicate, or otherwise respond to the detected or measured physical property. Examples may further include electronics to improve the functionality of these sensors. Improvement to the functionality may include, for example, increasing sensitivity and dynamic range of the sensor.

A micro hair sensor for measuring air flow speed and direction based on hydraulic amplification is disclosed as an example of a 3-D MEMS structure of the present disclosure. As used herein, “hair” or “hair-like” structure means a structure having a height extending outwardly from the substrate and a largest lateral dimension orthogonal to the height. The largest lateral dimension is smaller than the height. The term “height” is used as a name for a length dimension extending outwardly from the substrate. As such, even if a hair-like structure of the present disclosure extends from the substrate in the same direction as gravity, (i.e. downward) the hair-like structure would have a “height”. In an example, the hair-like structure may have a height of about 100 μm (micro meters) and a largest lateral dimension less than 100 μm.

Examples of the present disclosure include 3-D MEMS hair-like cores and arrays that may be fabricated on top of or immediately adjacent to CMOS (complementary metal-oxide-semiconductor)/electronics. In sharp contrast to structures that integrate passive electronics (piezoresistive, capacitive), examples of the present disclosure are integrated with active electronics. Active electronics generally include transistors, diodes or other electronic devices that allow more sophisticated functions such as multiplexing, amplification, filtering, analog-digital or digital-analog conversion, and many other signal processing functions to be performed. Another example of local electronics integration includes 3-D MEMS hair-like cores which are fabricated on top of or adjacent to operative materials such as a piezoelectric or thermoelectric material, etc. which convert energy from one form into another, such as between mechanical and electrical energy in the case of piezoelectrics.

MEMS hair-based structures' (e.g., sensors' and actuators') having 3-dimensional features according to examples of the present disclosure make them suitable for many emerging applications. The tall and small-footprint hair-like core provides a large mass and large surface to volume ratio, and has ability to incorporate different materials to fit a particular application. Current micro and nano-fabrication technologies make possible a myriad of geometries, materials and integration options. Large arrays of hair structures can be utilized to improve sensitivity, enhance selectivity, offer redundancy and robustness, increase dynamic range, and enhance functionality. The combination of the hair structure, efficient transduction techniques, and integrated electronics provides many desirable features. Large arrays of sensors can be fabricated in either extremely small areas, thus lowering cost, or on large distributed surfaces, thus increasing coverage. The hair structure can be used as, e.g., a sensor, an actuator, and/or passively used for achieving functions such as thermal management or filtering. One example of a passive hair includes a hair that absorbs light, heat or electrical energy to distribute it elsewhere, but the incoming stimuli might not be measured or otherwise “sensed.”

The hair-like structures of the present disclosure may be fabricated by any suitable method. For example, the hair-like structures may be produced monolithically on a planar substrate. In another example, the hair-like structures may be made with a hybrid method. As used herein, a hybrid method means the hairs are produced separately from the substrate and then transferred to the substrate. In yet another example, the hair-like structures may be formed from a raw material (e.g., wire, liquid materials, etc.) during a process for attaching the hair-like structure to the substrate.

Hair-like structures of the present disclosure may achieve a variety of functions including, for example: sensing of flow, temperature, vibration, sound, etc. In other examples, the hair-like structures may be used for actuation. In an example of the present disclosure, a hair-like structure actuator may be used for liquid manipulation and motion control. Examples of the hair-like structures may be used in passive structures for thermal control (cooling, heating, insulation) or environmental protection.

Some examples of hair-like structures of the present disclosure have a large surface-volume ratio, allowing the hair-like structure to interact efficiently with an environment external to the hair-like structure. Hair-like structures of the present disclosure thermally insulate when flat, and support heat transfer when raised. Some examples of the hair-like structures of the present disclosure may be raised or retracted to accentuate/minimize the function of the hair like structure. Examples of the hair-like structure may have an easily modifiable mechanical structure and shape, thus allowing the hair-like structures to be fabricated to have a wide range of mechanical properties. Examples of the hair-like structures may have a relatively high aspect ratio (i.e. height to maximum lateral dimension), thus producing a small foot print while providing a large mass and surface area.

Examples of the present disclosure include new device structures and fabrication methods for 3-D MEMS structures, e.g., including hair-like structures in biomimetic sensors and arrays. As used herein, “array” means any configuration of a plurality of 3-D MEMS structures. Examples of the array of the present disclosure include a rectilinear arrangement of the hair-like structures with perpendicular rows and columns. Other examples of arrays may have a star-shape, circular shape, spiral shape, or polygonal shapes, etc.

By combining mechanical sensing, local chemo-electric transduction, and sophisticated signal processing, sensors of the present disclosure provide unique capabilities that are beyond the abilities of any known sensor structure.

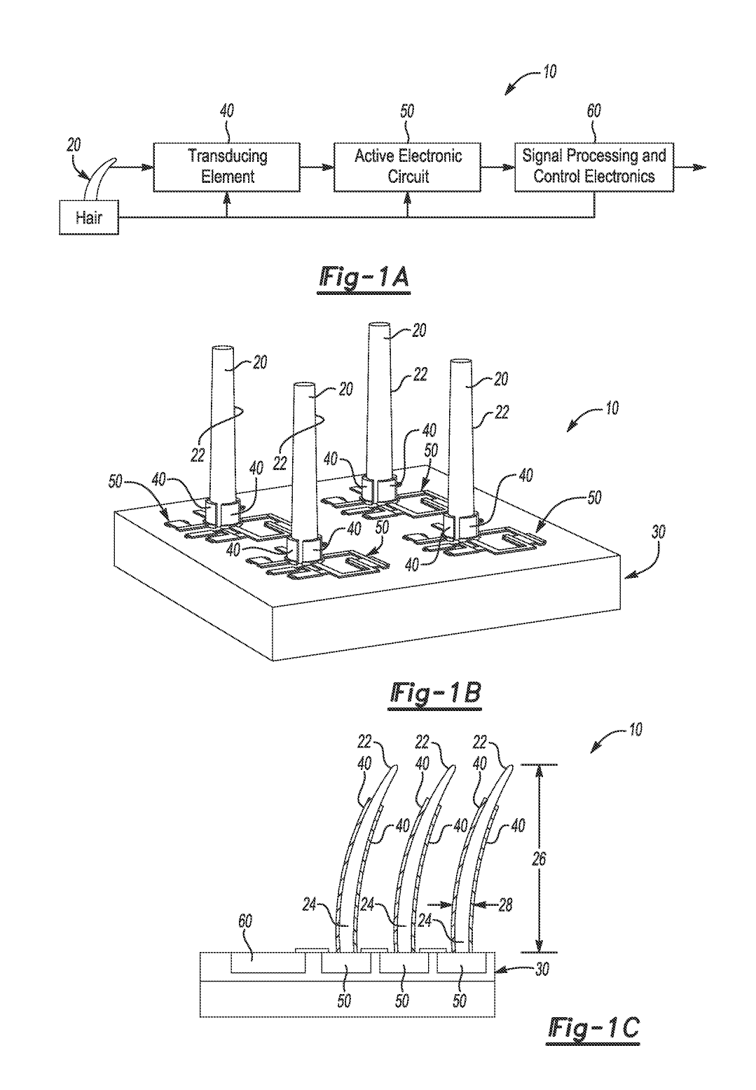

Referring now to FIGS. 1A, 1B and 1C together, examples of a 3-D MEMS structure with a hair-like core and a plurality of hair-like cores are depicted in biomimetic sensor systems of the present disclosure. Examples of the 3-D MEMS, structure 10 depicted in FIGS. 1A, 1B and 1C include a substrate 30 and a hair-like core 20. The height 26 of the hair-like core 20 extends outwardly from the substrate 30. A largest lateral dimension 28 orthogonal to the height 26 is smaller than the height 26. At least one transducing element 40 is operatively connected to the hair-like core 20. The operative connection may, for example, be a mechanical connection that allows the transducing element 40 to detect or measure a physical property of the hair-like core.

As shown in FIGS. 1B and 1C, the transducing element 40 may be formed on an outer surface 22 of the hair-like core 20. It is to be understood that the transducing element 40 may be fully or partially embedded within the hair-like core 20, formed on the outer surface 22 of the hair-like core 20, and/or disposed at a root 24 of the hair-like core. As used herein, the root 24 of the hair-like core 20 is an end portion of the hair-like core 20 that is mechanically connected to the substrate 30. There may be an intervening component or material disposed between the root 24 and the substrate 30. A transducing element 40 disposed at the root 24 of the hair-like core 20 may be on the substrate having a gap between the root 24 and the transducing element 40 smaller than twice the largest lateral dimension 28 of the hair-like core 20.

The transducing element 40 is to receive a core signal from the hair-like core 20. The core signal may be an electrical core signal or a non-electrical core signal. Examples of an electrical core signal include a voltage, current, and/or electrical waveform signals, etc. Examples of non-electrical core signals include magnetic, thermal, photonic, and/or mechanical signals etc. An example of a mechanical signal is a mechanical strain on the outer surface 22 of the hair-like core. The transducing element 40 may be, for example, a strain gage mounted on the hair-like core 20. In such an example, the strain gage receives the mechanical strain signal and produces an electrical output in response to the mechanical strain signal.

In an example of the present disclosure, the transducing element 40 is to convert the non-electrical core signal to an electrical output signal, or convert an electrical core signal (e.g., an electromagnetic signal) into an electrical output signal in a different format. In another example, the transducing element 40 may convert a non-electrical core signal to a different non-electrical output signal. For instance, the transducing element 40 may convert a mechanical strain to a pressure. In yet another example of the present disclosure, the transducing element 40 is to convert an electrical core signal to a non-electrical output signal. In such an example, the transducing element 40 may be, for example, a piezoelectric element that may be used as an actuator.

The transducing element 40 may receive an input signal from an active electronic circuit 50. For instance, the transducing element 40 may be a piezoelectric element that may be used to actuate the hair-like core 20.

Still referring to FIGS. 1A, 1B, and 1C, an active electronic circuit 50 is depicted underneath/adjacent the hair-like core 20 to condition the input signal to the transducing element 40, or the output signal from the transducing element 40. Signal conditioning means manipulating an electrical signal for use in another element of a system. For example, an electrical output signal from the transducing element 40 may be amplified and/or filtered by the active electronic circuit 50. The active electronic circuit 50 is operatively connected by monolithic or hybrid integration to at least a portion of the hair-like core 20 or to the transducing element 40. Examples of the 3-D MEMS structure that include the active electronic circuit may have improved sensitivity, selectivity, range, or function compared to the examples that do not have the active electronic circuit 50. The active electronic circuit 50 disposed at the root 24 of the hair-like core 20 may be on the substrate 30 having a gap between the root 24 and the active electronic circuit 50 smaller than twice the largest lateral dimension 28 of the hair-like core 20, or largest lateral dimension of the transducing element 40, whichever is larger.

In examples of the present disclosure, signal processing and control electronics 60 may be disposed on or integrated into the substrate 30 in electromagnetic communication with the active electronic circuit 50. The signal processing and control electronics 60 may ultimately process an output of a plurality of hair-like cores 20 and extract useful information by recording, indicating, or otherwise responding to the output of the hair-like cores 20.

The hair-like core 20 offers a number of advantages for sensing applications. The tall structure enables the hair-like core 20 to interact with a surrounding environment because the hair-like structure 20 provides a relatively large outer surface 22 for such interaction. The three dimensionality of the hair-like core 20 extending outwardly from the substrate 30 provides a relatively small footprint and better spatial resolution compared to a flat sensor disposed on a substrate. In examples of the present disclosure, the tall hair-like core 20 may mechanically amplify a signal of interest.

As depicted in FIG. 1C, the hair-like core 20 may be a mechanical substrate for the transducing element 40 while also interacting with the environment surrounding the hair-like core 20. A response of the hair-like core 20 to a stimulus or property of the surrounding environment is converted by the transducing element 40 as stated above. In examples of the present disclosure, the transducing element 40 may mimic a biological transduction function performed by chemical and neurotransmitter species that modulate the rate of firing of action potential in biological hair cells. In an example of the present disclosure, the transducing element 40 may include a thermocouple, piezoresistor, piezoelectric, magnetic, or other operative materials on the outer surface 22 of the hair-like core, or at the root 24 of the hair-like core 20 on a portion of the substrate 30 that supports the hair-like core 20. In an example, the material of the hair-like core 20 performs the transduction function without an additional transducing element 40 added to the hair-like core 20. For example, the hair-like core 20 may be made from a piezoelectric or thermoelectric material.

An electrical output from a combination of the hair-like core 20 and the transducing element 40 disclosed herein may be very small. Examples of the present disclosure may condition such electrical output to render an output that is more easily used. Still further, examples of the present disclosure may reduce an introduction of noise and/or attenuation of the signal by positioning at least a portion of the active electronic circuit 50 that performs conditioning directly at, adjacent to, or in close proximity to the root 24 of each hair-like core 20. Such positioning of the active electronic circuit 50 will help reduce parasitic losses and improved sensitivity. The active electronic circuit 50 may also perform many functions, such as improving selectivity through differential and common-mode signal processing, compensation for effects such as temperature, humidity, and vibration, and signal processing such as analog-digital conversion. In examples of the 3-D MEMS structure of the present disclosure, a combination of a single hair-like core 20 with a corresponding transducing element 40 and active electronic circuitry in a compact unit may be referred to as a “hexel”. An array of hexels may be used to spatially map a property of the environment detected by the array of hexels. As such, the meaning of the term “hexel” is analogous to the term “pixel” or “picture element” when used in reference to a CMOS image sensor.

A plurality of the hair-like cores 20 and respective transducing elements 40 may be arranged in an array on the same substrate 30. Respective active electronic circuits 50 may also be included in the array on the same substrate 30. Such an array may provide for fault tolerance, redundancy, and improved performance such as better sensitivity or wider dynamic range. Further, such an array may allow simultaneous detection or measurement of different properties in the environment. Due to the small footprint and three-dimensionality, the hair-like cores 20 of the present disclosure may be formed in large arrays (i.e. arrays having many elements) on a substrate 30, and the outputs of the large arrays may be monitored for specific response patterns.

In examples of the present disclosure, control electronics 60 may provide feedback and other information to the transducing element 40 or to the array to optimize performance in specific ways. An example of other information may be a mode selection. For example, if a stimulus is only using a small portion of the available dynamic range, the signal processing and control electronics 60 may cause a hexel to switch to a mode with a smaller dynamic range and greater sensitivity. The transducing element 40, the active electronic circuit 50, and/or the signal processing and control electronics 60 may be located under each hexel in a distinct portion of substrate, or disposed inside a continuous semiconducting substrate 30, including a polymeric substrate thin enough for mechanical flexibility.

The control electronics 60 may be used to control the operation of actuators in examples of the present disclosure. Such actuators may be part of or wholly substituted for the transducing elements 40. The actuators may be activated to enhance the ultimate output of each hair-like core 20 and respective transducing element 40. In another example, the actuator may be used for directly interfacing with the surrounding environment, such as in locomotion.

Examples of the 3-D MEMS structure disclosed herein may be fabricated using a variety of technologies and materials. These technologies include deep reactive-ion etching (DRIE) of silicon, polymer molding, metal electroforming, selective growth, inkjet printing, laser assisted polymerization and deposition, stamping, extrusion, electroforming, embossing, and many other technologies that were traditionally used for forming macro scale structures. The hair-like core 20 may be fabricated on a separate substrate and then transferred to a substrate 30 containing the other elements of the 3-D MEMS structure 10 through bonding or self-assembly. The hair-like core 20 may be directly formed on a substrate 30. Examples of hair-like cores 20 may be formed vertically extending outwardly from the substrate 30, or horizontally on the surface of the substrate 30 and then raised to a position so that the hair-like core 20 extends outwardly from the substrate 30. The hair-like core 20 may be raised from the surface of the substrate mechanically or by any suitable actuating technology. For example, the hair-like cores 20 may be selectively actuated to stand on their roots 24 or controlled to reach a specific vertical position to enhance a response of the hair-like core 20 to a stimulus.

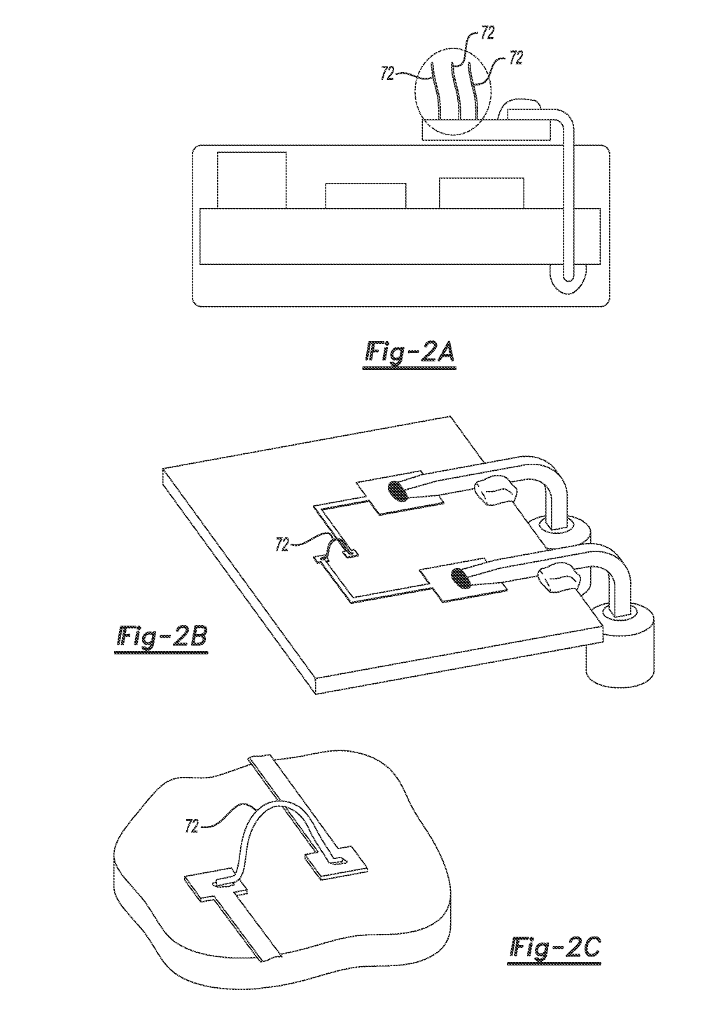

FIGS. 2A, 2B and 2C together depict a hot-wire air flow sensor 70 of the present disclosure. Hair-like cores 20 are very effective in measuring air flow speed and direction. In an example, air flow is measured using a system based on bond wires 72 and thermal sensors. FIGS. 2A, 2B and 2C together show a low-cost and high-performance hot-wire air flow sensor 70 which utilizes a bond-wire 72 as the sensing element. Arrays of such hot-wire air flow sensors 70 may be fabricated. The bond wire 72 may be made of aluminum or platinum and attached to the substrate 30 using standard wire bond techniques commonly used in the IC (integrated circuit) industry. The bond-wire 72 extends outwardly from the surface of the substrate 30. In operation, the bond-wire 72 is heated by passing a current there through. The wire is cooled more by greater airflow. The resistance of the bond wire 72 corresponds to a temperature of the bond wire 72. Therefore, the resistance of the bond wire 72 is responsive to air flow. The example of the hot-wire anemometer depicted in FIGS. 2A, 2B and 2C offers high accuracy, high sensitivity and wide dynamic range. Aluminum and platinum wire flow sensors have been successfully fabricated and achieved a measurement range from about 2.5 cm/s to about 17.5 msec, with an accuracy of 2 mm/s at low flow regime (<50 cm/s) and 5 cm/s at high flow regime (>2 m/s). Active electronic circuits 50 for processing the output signal may be fabricated for each bond-wire 72 and provide improved performance.

In examples, the 3-D MEMS structures 10 could integrate the electronics, e.g., underneath, on the side of, or embedded within the hair-like core 20, thus providing a much higher spatial and temporal resolution. Examples of the present disclosure may include 3-D MEMS structures 10 with both monolithic electronics (e.g., co-fabricated or integrated alongside the 3-D MEMS), and/or hybrid electronics (e.g., substrate having a hair-like core 20 attached thereto may be fabricated separately from the active electronic circuit 50 with subsequent attachment of the substrate having the hair-like core 20 and the active electronic circuit 50 together). In examples of the present disclosure, each 3-D MEMS structure 10 may have some electronics. The electronics may be a switch for multiplexing, or the electronics may include more sophisticated electronics, e.g., for processing the signal from the hair-like core 20.

The sensitivity of the sensor based on the hair-like core 20 may be significantly improved by using certain transduction techniques, including piezoresistive, capacitive, magnetic, and piezoelectric transduction. Of the transduction techniques disclosed above, capacitive techniques may provide the highest sensitivity while occupying a small area and dissipating low power. Capacitive sensing may be used to achieve excellent performance for acoustic and air flow sensing.

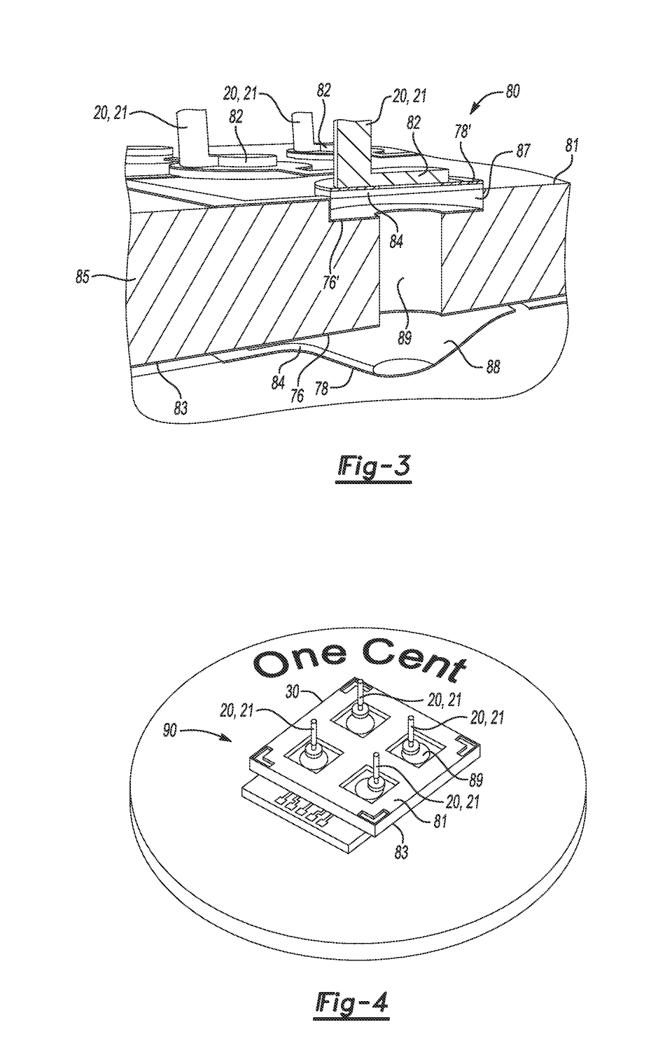

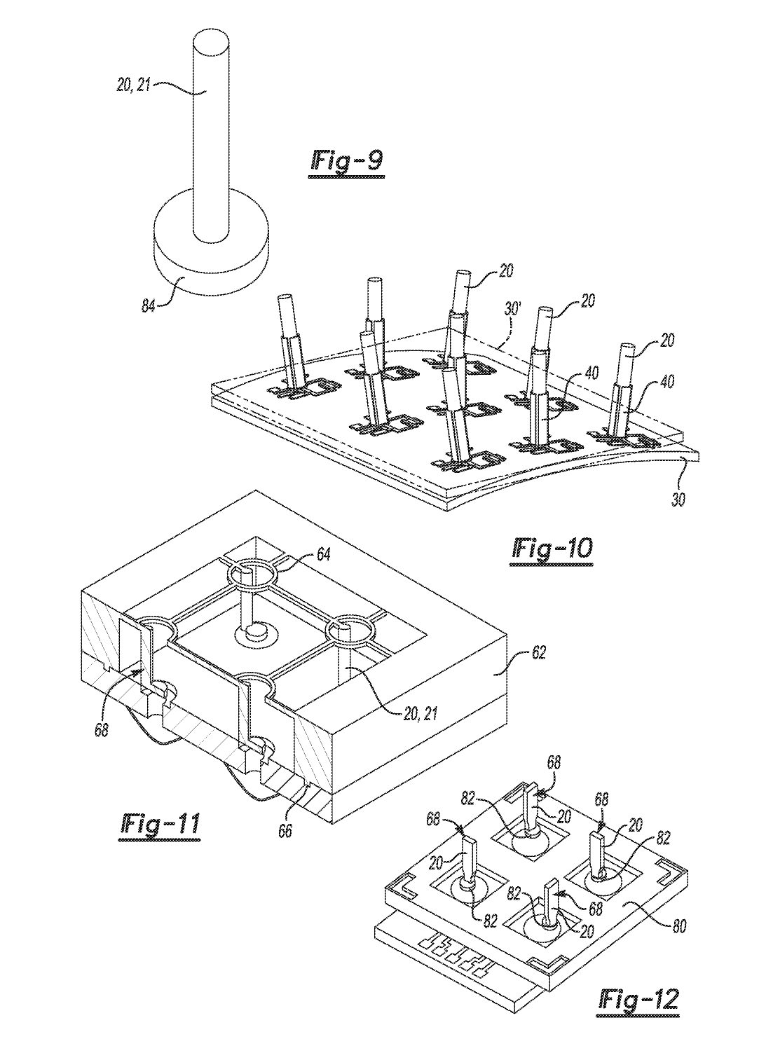

FIG. 3 depicts a micro-hydraulic structure 80 with hair-like cores 20 attached on a bossed membrane 84 according to the present disclosure. The example combines capacitive sensing and hydraulic amplification to achieve wide dynamic range and robustness. The sensitive capacitive transducing element 40 is protected from environment sources of noise and error (e.g. humidity). The example has good dynamic and full-scale range with high sensitivity. The present inventors have unexpectedly and fortuitously discovered the disclosed micro-hydraulic structure 80 that utilizes fluid amplification to enhance the sensitivity of the air flow sensor. The micro-hydraulic structure 80 has hair-like cores 20 attached on a bossed membrane 84. After integration of the boss 82, a silicone elastomer epoxy, for example, may be used to attach the tall hair-like core 20 over the boss 82. The micro-hydraulic structure 80 includes a first chamber 87 on the front side 81 and a second chamber 88 on the back side 83 of a silicon wafer 85 fluidly connected through the silicon wafer 85 by a channel 89. Both chambers 87, 88 and the channel 89 are filled with a silicone fluid; and the chambers 87, 88 are capped by a 1-2 μm layer of Parylene to enclose the micro-hydraulic system. Either the first chamber 87 or the second chamber 88 may be compressed by applying pressure to the flexible Parylene membrane on one side, thus forcing the silicone fluid into the other chamber, causing the membrane of the other chamber to deflect. An area ratio between the chambers 87, 88 determines an amount of amplification of either force or displacement. The amplification characteristic of the micro-hydraulic system, contributes to improving sensor performance of the micro-hydraulic structure 80. A pair of electrodes 76, 78 on the back side (corresponding to the second chamber 88) may be used for electrostatic actuation or capacitive sensing. A second pair of electrodes 76′, 78′ corresponding to the first chamber 87 may provide capacitive sensing or actuation of the first chamber 87. A hair-like core 20 in a configuration as a hair-like post 21 may be used to convert drag force caused by fluid flow into pressure that is applied on the membrane 84. Examples of the present disclosure use prefabricated pins (see FIG. 9) as the hair-like post 21 attached to the front-side Parylene membrane 84 with silicone elastomer epoxy.

FIG. 4 shows a flow sensor array 90 of four hair-like cores 20 configured as hair-like posts 21 used for sensing flow speed and direction. The micro-hydraulic channel 89 connecting the front side 81 to the back side 83 of the substrate 30 is depicted under each hair-like core 20. The membranes 84 are deposited all at once as a single film, but between the channels 89 the membranes 84 are attached to the substrate 30, forming a film coating on the substrate 30. This is an example of hair-like cores 20 on flexible substrates or resilient membranes 84. The flow sensor array 90 offers a large air flow speed measurement range, high sensitivity and high bandwidth, e.g., of about 30 Hz. The flow sensor array 90 responds linearly to increasing flow speed from 0 to 15 m/s. The sensitivity is estimated to be slightly over 2 cm/s. It is to be understood that the flow sensor array 90 may also be replicated via batch fabrication. The flow sensor array 90 is shown on a coin approximately the size of a United States cent to convey the approximate size of the sensor array 90.

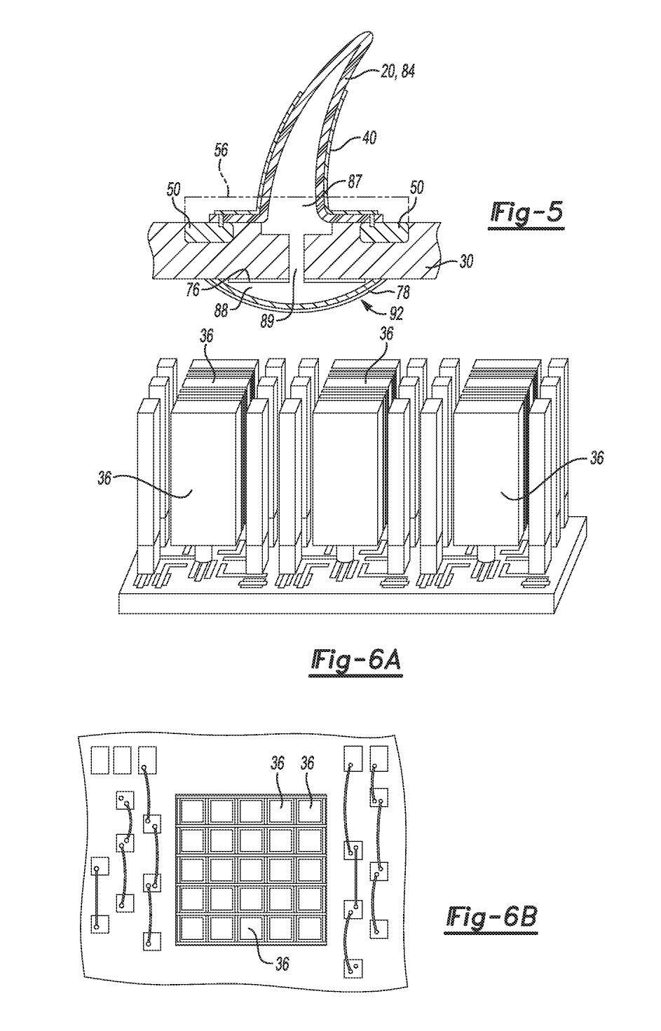

FIG. 5 shows an example of a 3-D MEMS structure integrated with electronics according to an example of the present disclosure. The device shown in FIG. 5 is similar to the devices shown in FIGS. 3 and 4, except the hair-like core 20 also acts like the membrane 84 and is filled with fluid. Hydraulics/fluidics are depicted at 92. In this example, the transducing element 40 is the curved capacitive electrode pair 76 and 78 on the back side of the substrate 30, and the “hexel” size 56 is defined by the area in which the transducing element 40 and active electronic circuit 50 are contained. Therefore, when an array of hair sensors are made, active circuitry will be distributed over the array i.e. signal amplification and/or initial/partial processing is performed locally.

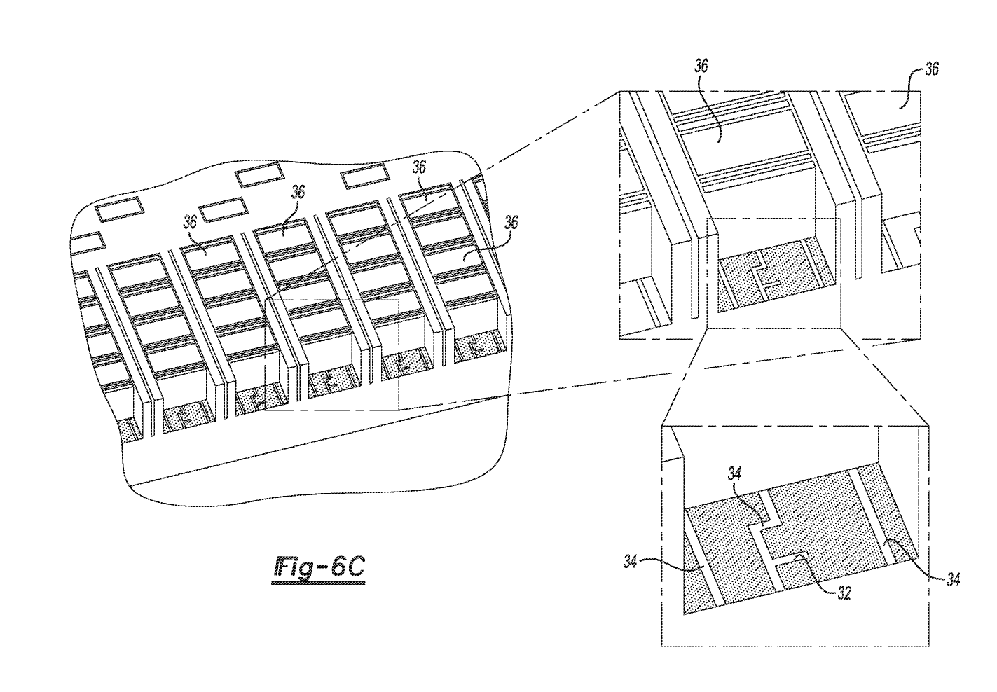

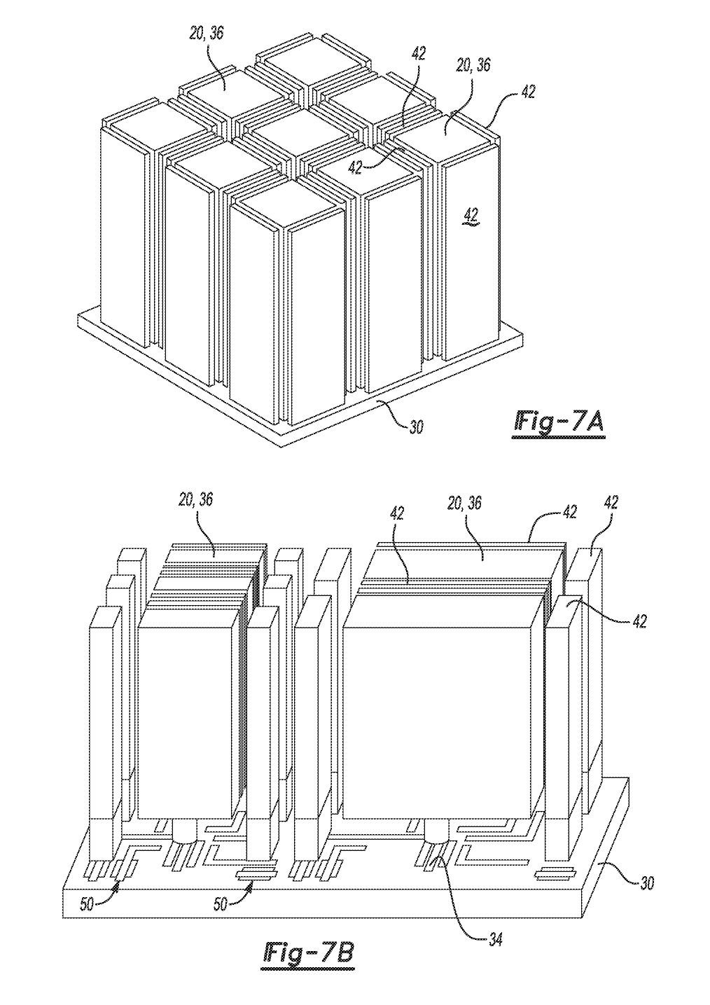

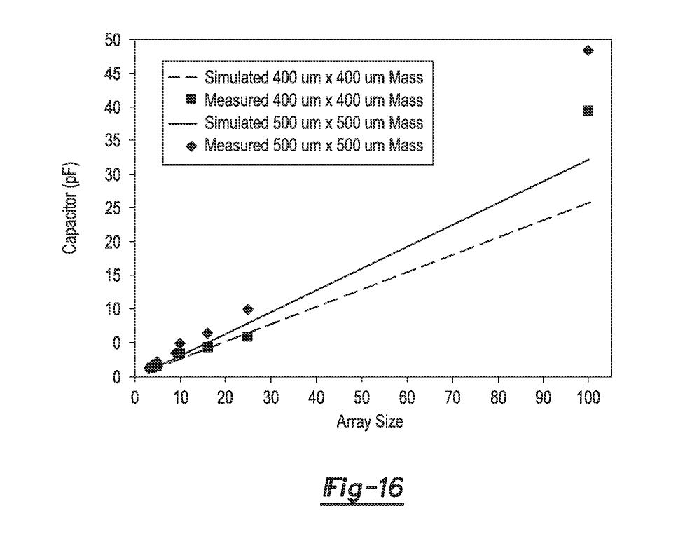

FIG. 6A shows another example of an array of 3-D MEMS structures integrated with circuitry according to an example of the present disclosure. FIGS. 6B and 6C are examples of implementations of FIG. 6A. To effectively readout large sensor arrays in these example implementations and to achieve greater sensitivity, all devices are connected in parallel (FIGS. 6B and 6C). The post bond location is depicted at reference numeral 32 (with mass detached to show detail). Metal connectors are shown at reference numeral 34. The maximum realized sensor density may be high (100 sensors/mm²). Initial tests show static capacitance that scales almost linearly with array size (see FIG. 16). FIG. 16 shows initial testing results from the structure depicted in FIG. 6B. The static capacitance measurement compared with simulated values assuming an average capacitive gap of 5.5 μm for 400 μm×400 μm and 500 μm×500 μm mass. FIG. 16 shows that the static capacitance scales almost linearly with array size.

FIG. 7A shows an example of an array of similar elements. FIG. 7B shows yet another example of an array of 3-D MEMS structures, but having different sizes and shapes, made of different materials, and all on the same substrate 30. Structures with different dimensions may offer different ranges of operation. When combined, the total range of operation may be greater than that of any one sensor alone. This is in contrast to more simple arrays of identical hair-like structures. It is to be understood that examples of the sensors of the present disclosure may be combined in series or in parallel and can include local signal processing using underlying CMOS circuitry. In an example of the present disclosure, the structure (e.g., shown in FIG. 7C) implements 2-axis capacitive acceleration sensor arrays. Each sensor includes a proof mass 36 atop a narrow post 38. The post 38 acts as a mechanical spring, and the mass 36 is surrounded by four walls 42 for capacitive sensing of deflection. Metal connectors are depicted at reference numeral 34. Examples of active electronic circuits 50 are shown on the substrate 30 in FIG. 7B.

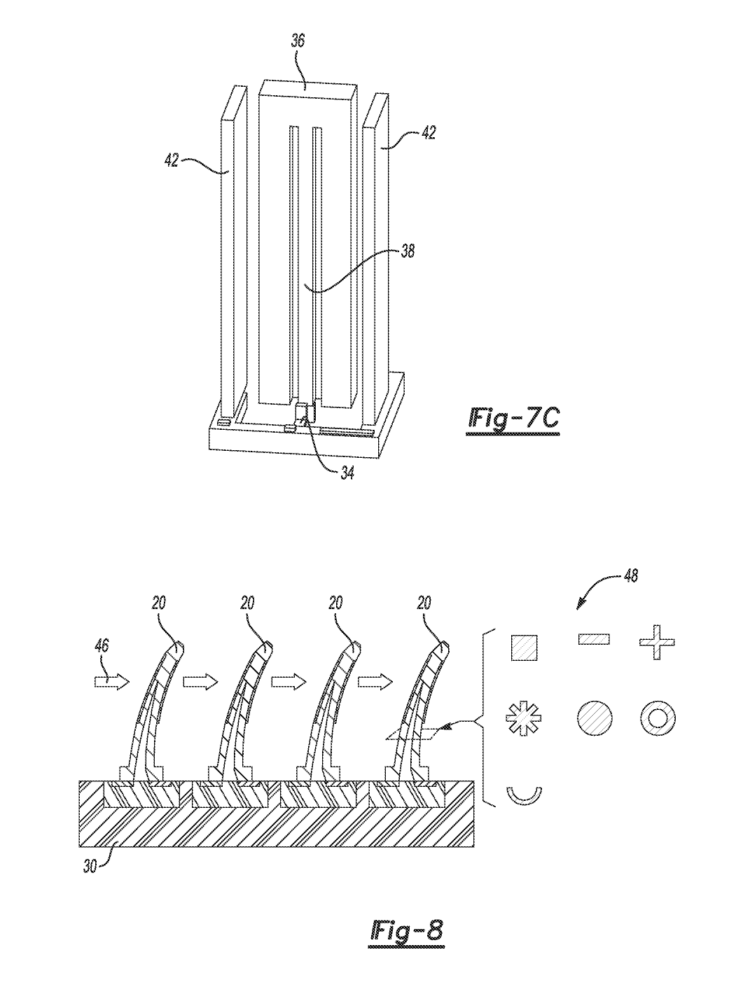

FIGS. 7B and 8 are two examples of hair-like structures with different materials, surface treatments/coatings, sizes, or shapes, integrated on the same substrates 30. In the example depicted in FIGS. 7A, 7B, and 7C, the walls 42 may be made from different materials than the mass 36. In FIG. 8, the hair-like cores 20 in an array can be made of different materials or different shapes or different dimensions so they can be responsive to different parameters or different parametric ranges for sensing or generating different non-electrical signals for actuators. Examples of several possible hair-like core cross-sections are shown at 48. It is to be understood that there are many other suitable cross-sectional shapes not shown, and these other shapes are considered to be within the scope of the present disclosure. The hair-like cores 20 may have different shapes and cross-sections to make them more suitable for a given application. The hair-like core 20 may be formed using a variety of techniques. Further, it is to be understood that the hair-like cores 20 may have a hollow, solid, or reticulated structure. A reticulated structure is net-like or grid-like, i.e. the walls of the hair-like core 20 may have holes in them and are not required to be solid. The hair-like core 20 may be partially solid, partially hollow or any combination thereof.

FIG. 9 shows a large (e.g., about 2 mm long) 3-D pin (“hair”) integrated on top of a flexible Parylene membrane 84.

Referring to FIG. 10, the substrate that supports the hair-like cores 20 and the active electronic circuits 50 may be thin, or made of compliant materials so that the entire substrate 30 has mechanical flexibility and is able to conform to different form factors.

FIG. 11 is a schematic drawing of an integrated hair-boss 68 along with a support rim 62 and tethers 64 in an SLA (stereo lithography apparatus) framework positioned on top of micro-hydraulic structure 80.

Referring now to FIG. 12, another approach to fabricate an array of 3-D hair-like cores 20 is to use stereo-lithography. The fabricated 3-D hair-like cores 20 can be attached to the micro-hydraulic structure 80 at the die or possibly the wafer level. This technique allows for precise positioning of the hair-like core 20 over the micro-hydraulic sensing cells. Stereo-lithography is a fast and low-cost method for making arrays of complex 3-D parts. Stereo-lithography allows for accurate control over hair-boss 68 geometry, including various hair-like core 20 cross-sections/shapes and lengths. For instance, long, flat, sail-like hair-like cores 20 result in larger drag force and higher sensitivity. The hair-boss 68 structure (hair-like core 20 with boss 82 attached to the hair-like core 20) and its dimensions can be optimized to further improve the sensitivity of hair-like air flow sensors. Intentional asymmetries in the design of the integrated hair-boss 68, along with off-center positioning of the hair-like cores 20 on top of micro-hydraulic structure 80, are used to build a 2-D directional flow sensor using an array of four hair-like air-flow sensors. Stereo-lithography apparatus (SLA) may be used to build the hair-bosses 68 within a support rim 62, connected by tethers 64. (See FIG. 11.) This framework holds the hair-boss 68 in place while it is attached to the micro-hydraulic structure 80 chip, using rims/grooves 66 (FIG. 11) for mechanical alignment. Epoxy is applied to the bosses 82 by stamping, and the bosses 82 are brought into contact with the Parylene membranes 84. After adhesion, the support tethers 64 are cut, releasing the hair-like cores 20 (FIG. 12).

The maximum measured hair-like air flow sensitivity is 47.9 fF/(m·s⁻¹), a ten-fold increase over our previous uni-directional air-flow sensor. The new sensor dynamic range is 0-15 m·s⁻¹, with an extrapolated minimum detection limit of about 2 mm·s⁻¹, and an angular resolution of 13°.

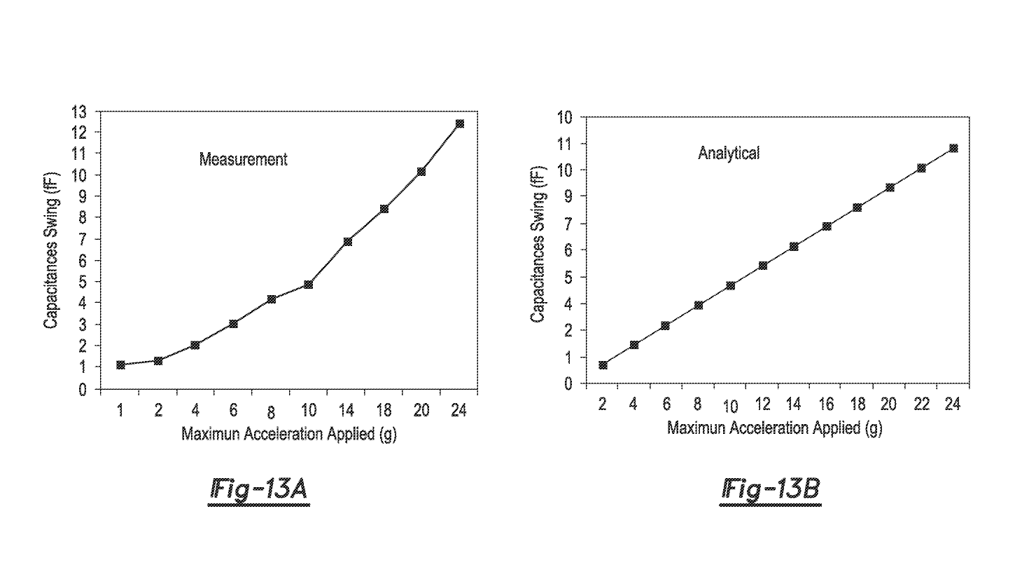

FIGS. 13A and 13B presents the vibration table measurement result of a 5×5 acceleration sensor array. FIG. 13A shows results from a maximum acceleration level sweep from 1 g to 24 g at 40 Hz excitation frequency. This array has a sensitivity of 0.5 fF/g (femtofarad per g). FIG. 13B is the analytical result for comparison.

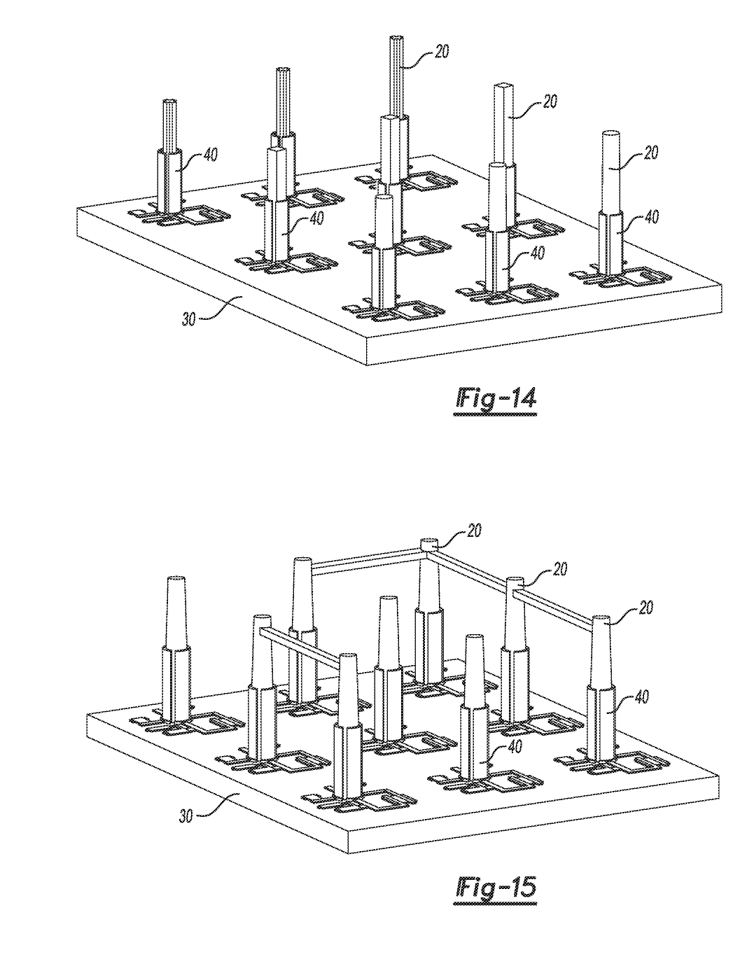

FIG. 14 semi-schematically shows an example of an array of hair-like cores 20 arranged to make sensors with various heights, cross sections and materials on the same substrate. Each sensor may be used for a specific range of measurement or frequency. The different hair-like cores can also sense different measurands if the functionalizing material (transducing element 40) varies.

FIG. 15 shows a semi-schematic perspective view of multiple connected hair-like cores 20. The connected hair-like cores 20 may amplify sensor overall performance, such as sensitivity improvement, or add new functionality to the hair sensor arrays.

It is to be understood that the ranges provided herein include the stated range and any value or sub-range within the stated range. For example, a range of about 0 m/s to about 15 m/s should be interpreted to include not only the explicitly recited limits of about 0 m/s to about 15 m/s, but also to include individual values, such as 3 m/s, 8 m/s, 12 m/s, etc., and sub-ranges, such as 2 m/s to about 10 m/s, 5 m/s to about 9 m/s, etc. Furthermore, when “about” or “approximately” or the like is/are utilized to describe a value, this is meant to encompass minor variations (up to +/−10 percent) from the stated value.

Further, the terms “connect/connected/connection” and/or the like are broadly defined herein to encompass a variety of divergent connected arrangements and assembly techniques. These arrangements and techniques include, but are not limited to (1) the direct connection between one component and another component with no intervening components therebetween; and (2) the connection of one component and another component with one or more components therebetween, provided that the one component being “connected to” the other component is somehow operatively connected to the other component (notwithstanding the presence of one or more additional components therebetween).

Reference throughout the specification to “one example”, “another example”, “an example”, and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

In describing and claiming the examples disclosed herein, the singular forms “a”, “an”, and “the” include plural referents unless the context clearly dictates otherwise.

While several examples have been described in detail, it will be apparent to those skilled in the art that the disclosed examples may be modified. Therefore, the foregoing description is to be considered non-limiting.

What is claimed is:

1. A three-dimensional microelectromechanical systems (3-D MEMS) structure, comprising:
a substrate;
a hair-like core having a height extending outwardly from the substrate and a largest lateral dimension orthogonal to the height wherein the largest lateral dimension is smaller than the height; and
a transducing element operatively connected to the hair-like core and embedded within, formed on an outer surface of, or disposed at a root of the hair-like core, the transducing element to receive an electrical core signal or a non-electrical core signal conveyed by the hair-like core, wherein the transducing element is to:
i) convert the non-electrical core signal to an electrical output signal;
ii) convert the electrical core signal to an electrical output signal in a different format;
iii) convert the non-electrical core signal to a different non-electrical output signal; or
iv) convert the electrical core signal to a non-electrical output signal.

2. The 3-D MEMS structure as defined in claim 1, further comprising an active electronic circuit operatively connected by monolithic or hybrid integration to at least a portion of the hair-like core or to the transducing element to:
i) condition the transducing element output signal and modify a sensitivity and a selectivity of the MEMS structure;
ii) actuate or mechanically manipulate the MEMS structure in response to the electrical core signal or the non-electrical core signal conveyed by the hair-like core; or
iii) electrically interact with the hair-like core or the transducing element.

3. The 3-D MEMS structure as defined in claim 1 wherein the 3-D MEMS structure is to measure at least one of acceleration, angular rotation, rotation rate, and other inertial forces.

4. The 3-D MEMS structure as defined in claim 3, further comprising:
an array of the hair-like cores;
wherein the array is to measure at least one of acceleration, angular rotation, rotation rate, and other inertial forces.

5. The 3-D MEMS structure as defined in claim 1 wherein the hair-like core is mounted on a flexible substrate or on a resilient membrane disposed on or defined by the substrate.

6. The 3-D MEMS structure as defined in claim 5, further comprising:
an array of the hair-like cores;
wherein:
each hair-like core in the array of the hair-like cores is mounted on the flexible substrate, or each hair-like core in the array of the hair like cores is mounted on a respective resilient membrane in a plurality of resilient membranes;
each resilient membrane is integrated on or attached to the substrate; and
the substrate is a common substrate for the plurality of resilient membranes.

7. The 3-D MEMS structure as defined in claim 2 wherein the substrate is a flexible substrate or the hair-like core is mounted on a resilient membrane disposed on the substrate.

8. The 3-D MEMS structure as defined in claim 2, further comprising an array including:
a plurality of the hair-like cores spaced on the substrate; and
a plurality of the active electronic circuits, each of the active electronic circuits of the plurality of active electronic circuits operatively connected to at least a portion of a respective hair-like core or to a respective transducing element corresponding to the respective hair-like core.

9. The 3-D MEMS structure as defined in claim 8 wherein:
the plurality of hair-like cores is disposed on or part of the same substrate; and
a value of a property corresponding to at least one hair-like core of the plurality of hair-like cores is non-identical or non-homogeneous to an other value of the property corresponding to an other hair-like core of the plurality of hair-like cores; and
the property includes a spatial size, a shape, a material, a structure or combinations thereof.

10. The 3-D MEMS structure as defined in claim 8 wherein:
the plurality of hair-like cores is disposed on or part of the same substrate;
at least one of the respective transducing elements corresponding to the respective hair-like core converts the respective electrical core signal or non-electrical core signal via a different transfer function compared to an other of the respective transducing elements corresponding to an other of the respective hair-like cores.

11. The 3-D MEMS structure as defined in claim 8 wherein:
the plurality of hair-like cores is disposed on or part of the same substrate;
at least one of the respective active electronic circuits corresponding to the respective hair-like core is operatively different compared to an other of the respective active electronic circuits corresponding to an other of the respective hair-like cores.

12. The 3-D MEMS structure as defined in claim 8 wherein the substrate is a flexible substrate and each hair-like core of the plurality of hair-like cores is mounted on the flexible substrate.

13. The 3-D MEMS structure as defined in claim 8 wherein:
each hair-like core of the plurality of hair-like cores is mounted on a respective resilient membrane in a plurality of resilient membranes;
each resilient membrane is integrated on or attached to the substrate; and
the substrate is a common substrate for the plurality of resilient membranes.

14. The 3-D MEMS structure as defined in claim 8 wherein the array is to measure at least one of acceleration, angular rotation, forces, rotation rate, and inertial forces.

15. A three-dimensional microelectromechanical systems (3-D MEMS) structure, comprising:
a substrate;
an array of hair-like cores, each of the hair-like cores having a respective height extending outwardly from the substrate and a largest lateral dimension orthogonal to the height wherein the largest lateral dimension is smaller than the height,; and
a plurality of transducing elements, each transducing element in the plurality of transducing elements operatively connected to a respective hair-like core and embedded within, formed on an outer surface of, or disposed at a root of the respective hair-like core, each transducing element in the plurality of transducing elements to receive an electrical core signal or a non-electrical core signal conveyed by the respective hair-like core, wherein each transducing element is to:
i) convert the non-electrical core signal to an electrical output signal;
ii) convert the electrical core signal to an electrical output signal in a different format;
iii) convert the non-electrical core signal to a different non-electrical output signal; or
iv) convert the electrical core signal to a non-electrical output signal;
wherein the array of hair-like cores is disposed on the same substrate; and
wherein a value or description of a property corresponding to at least one hair-like core in the array of hair-like cores is non-identical or non-homogeneous to an other value or description of the property corresponding to an other hair-like core of the array of hair-like cores; and the property includes a spatial size, a shape, a material, a structure or combinations thereof.

16. The 3-D MEMS structure as defined in claim 15 wherein at least one of the transducing elements corresponding to a respective hair-like core converts the respective electrical core signal or non-electrical core signal via a different transfer function compared to an other of the transducing elements corresponding to an other of the respective hair-like cores.

17. The 3-D MEMS structure as defined in claim 15 wherein the at least one hair-like core has a hollow, solid, or reticulated structure.

18. A three-dimensional microelectromechanical systems (3-D MEMS) structure, comprising:
a substrate;
a transducing hair-like core having a height extending outwardly from the substrate and a largest lateral dimension orthogonal to the height wherein the largest lateral dimension is smaller than the height; wherein the transducing hair-like core is a transducing element composed of an operative material to receive an electrical stimulus or a non-electrical stimulus, wherein the transducing hair-like core is to:
i) convert the non-electrical stimulus to an electrical output signal;
ii) convert the electrical stimulus to an electrical output signal in a different format;
iii) convert the non-electrical stimulus to a different non-electrical output signal; or
iv) convert the electrical stimulus to a non-electrical output signal.

19. The 3-D MEMS structure as defined in claim 18, further comprising an active electronic circuit operatively connected by monolithic or hybrid integration to at least a portion of the transducing hair-like core to:
i) condition the transducing hair-like core output signal and modify a sensitivity and a selectivity of the MEMS structure;
ii) actuate or mechanically manipulate the MEMS structure in response to the transducing hair-like core; or
iii) electrically interact with the transducing hair-like core.

20. The 3-D MEMS structure as defined in claim 18, further comprising:
an array of the transducing hair-like cores;
wherein the array is to measure at least one of acceleration, angular rotation, rotation rate, and inertial forces.
